(19) United States
(12) Patent Application Publication
(10) Pub. No.: US 2025/0029956 A1
(43) Pub. Date: Jan. 23, 2025

(54) SEMICONDUCTOR MEMORY DEVICE

(71) Applicant: Kioxia Corporation, Tokyo (JP)

(72) Inventors: Yasunori IWASHITA, Yokkaichi Mie (JP); Hisashi KATO, Yokkaichi Mie (JP); Hiroaki ASHIDATE, Mie Mie (JP); Masayoshi TAGAMI, Kuwana Mie (JP)

(21) Appl. No.: 18/777,303

(22) Filed: Jul. 18, 2024

(30) Foreign Application Priority Data
Jul. 21, 2023 (JP) 2023-119236

(51) Int. Cl. H01L 25/065; G11C 16/04; H01L 23/522; H01L 23/528; H01L 23/532; H10B 43/10; H10B 43/20; H10B 43/35; H10B 80/00

(52) U.S. Cl. CPC H01L 25/0657; G11C 16/0483; H01L 23/5226; H01L 23/5283; H01L 23/53295; H10B 43/10; H10B 43/20; H10B 43/35; H10B 80/00; H01L 2225/06541

(57) ABSTRACT

A semiconductor memory device includes first and second chips that are bonded together. The first chip includes a stacked body in which memory cells are formed and first bonding electrodes, and the second chip includes second bonding electrodes. The first bonding electrodes and the second bonding electrodes are joined to each other to form joining electrodes. The stacked body includes an insulating layer that extends in a first direction to separate the stacked body in a second direction. The joining electrodes include first and second joining electrodes, the first joining electrodes being disposed adjacent to a first side of the insulating layer in a third direction, and the second joining electrodes being disposed adjacent to a second side of the insulating layer in the third direction. The first joining electrodes and the second joining electrodes are disposed in a staggered arrangement in the second direction and the third direction.

### CROSS-REFERENCE TO RELATED APPLICATION(S)

This application is based upon and claims the benefit of priority from Japanese Patent Application No. 2023-119236, filed Jul. 21, 2023, the entire contents of which are incorporated herein by reference.

### FIELD

Embodiments described herein relate generally to a semiconductor memory device.

### BACKGROUND

A NAND flash memory in which memory cell transistors are arranged three-dimensionally is known.

### DESCRIPTION OF THE DRAWINGS

FIG. 1 is a block diagram illustrating a schematic configuration of a memory system including a semiconductor memory device according to a first embodiment.

FIG. 2 is a circuit diagram illustrating an equivalent circuit of a memory cell array in the semiconductor memory device according to the first embodiment.

FIG. 3 is a cross-sectional view illustrating a cross-sectional structure of the semiconductor memory device according to the first embodiment.

FIG. 4 is an enlarged cross-sectional view illustrating a cross-sectional structure around a memory pillar of the semiconductor memory device according to the first embodiment.

FIG. 5 is a cross-sectional view illustrating a cross-sectional structure taken along line V-V in FIG. 3.

FIG. 6 is a cross-sectional view illustrating a cross-sectional structure around a bonding pad and a dummy pad of the semiconductor memory device according to the first embodiment.

FIG. 7 is a cross-sectional view illustrating a cross-sectional structure taken along line VII-VII in FIG. 6.

FIG. 8 is a cross-sectional view illustrating a cross-sectional structure of a semiconductor memory device according to a comparative example.

FIG. 9 is a cross-sectional view illustrating a cross-sectional structure around a bonding pad of a semiconductor memory device according to a second embodiment.

FIG. 10 is a cross-sectional view illustrating a cross-sectional structure of the semiconductor memory device according to the second embodiment.

FIG. 11 is a cross-sectional view illustrating a cross-sectional structure of a semiconductor memory device according to a first modification example of the second embodiment.

FIG. 12 is a cross-sectional view illustrating a cross-sectional structure of a semiconductor memory device according to a second modification example of the second embodiment.

FIG. 13 is a cross-sectional view illustrating a cross-sectional structure of a semiconductor memory device according to a third modification example of the second embodiment.

### DETAILED DESCRIPTION

Embodiments provide a semiconductor memory device capable of reducing the formation of voids.

In general, according to one embodiment, a semiconductor memory device includes a first chip having a first bonding surface and a second chip having a second bonding surface and bonded to the first chip. The first chip includes a stacked body where a plurality of first conductive layers and a plurality of first insulating layers are alternately stacked in a first direction, a memory pillar that penetrates the stacked body in the first direction to form memory cell transistors at intersections with the first conductive layers, and a plurality of first bonding electrodes provided on the first bonding surface and to which the second chip is bonded. The second chip includes a plurality of second bonding electrodes provided on the second bonding surface and to which the first chip is bonded. The plurality of first bonding electrodes and the plurality of second bonding electrodes are joined to each other to form a plurality of joining electrodes. The stacked body extends in a second direction intersecting with the first direction and includes a second insulating layer that extends in the first direction in the stacked body such that at least a part of the stacked body is separated in a third direction intersecting with both of the first direction and the second direction. The plurality of joining electrodes include a plurality of first joining electrodes and a plurality of second joining electrodes, the first joining electrodes being disposed adjacent to a first side of the second insulating layer and at a first predetermined interval along the second direction, and the second joining electrodes being disposed adjacent to a second side of the second insulating layer in the third direction and at a second predetermined interval along the second direction. The plurality of first joining electrodes and the plurality of second joining electrodes are disposed in a staggered arrangement in the second direction and the third direction.

Hereinafter, an embodiment will be described with reference to the drawings. For easy understanding of the description, in the drawings, the same components are represented by the same reference numerals, and the description thereof will not be repeated.

### 1. FIRST EMBODIMENT

A semiconductor memory device according to a first embodiment will be described. The semiconductor memory device according to the present embodiment is a nonvolatile memory device that is configured as a NAND flash memory.

### 1.1 Configuration of Semiconductor Memory Device

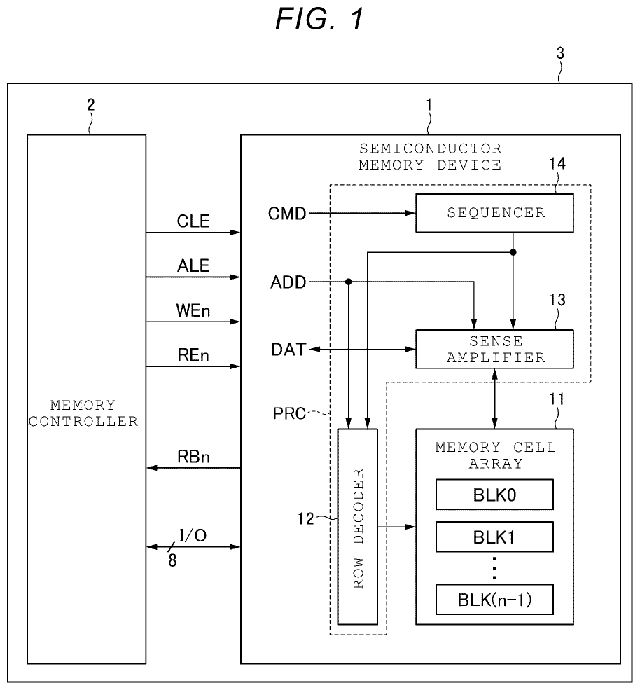

FIG. 1 is a block diagram illustrating an example of a schematic configuration of a memory system 3 including a semiconductor memory device 1 according to the first embodiment. The semiconductor memory device 1 is controlled by an external memory controller 2. A combination of the semiconductor memory device 1 and the memory controller 2 make up the memory system 3. The memory system 3 is, for example, a memory card such as an SD™ card or a solid state drive (SSD).

Communication between the semiconductor memory device 1 and the memory controller 2 is carried out according to, for example, NAND interface standards. For the communication between the semiconductor memory device 1 and the memory controller 2, for example, a command latch enable signal CLE, an address latch enable signal ALE, a write enable signal WEn, a read enable signal REn, a ready/busy signal RBn, and an input/output signal I/O arc used.

The input/output signal I/O is, for example, an 8-bit signal, and may include a command CMD, address information ADD, and data DAT. Hereinafter, both write data and read data are represented by reference numeral DAT in the description. The semiconductor memory device 1 receives the command CMD, the address information ADD, and the write data DAT from the memory controller 2 through the input/output signal I/O.

The command latch enable signal CLE is used for notifying the semiconductor memory device 1 of a period where the command CMD is transmitted through the signal I/O. The address latch enable signal ALE is used for notifying the semiconductor memory device 1 of a period where the address information ADD is transmitted through the signal I/O. The write enable signal WEn is used for enabling the semiconductor memory device 1 to input the signal I/O. The read enable signal REn is used for enabling the semiconductor memory device 1 to output the signal I/O. The ready/busy signal RBn is used for notifying the memory controller 2 of whether the semiconductor memory device 1 is in a ready state or a busy state. In the ready state, the semiconductor memory device 1 can receive a command from the memory controller 2. In the busy state, the semiconductor memory device I cannot receive a command from the memory controller 2 with few exceptions.

The semiconductor memory device 1 includes a memory cell array 11 and a peripheral circuit PRC. The peripheral circuit PRC includes a row decoder 12, a sense amplifier 13, and a sequencer 14. The memory cell array 11 includes blocks BLK0 to BLK(n-1) (n represents an integer of 1 or more). The block BLK includes a plurality of nonvolatile memory cells associated with bit lines and word lines and is, for example, a unit of erasing data.

The sequencer 14 controls an overall operation of the semiconductor memory device 1 based on the received command CMD. For example, the sequencer 14 controls the row decoder 12, the sense amplifier 13, and the like to execute various operations such as a write operation and a read operation. In the write operation, the write data DAT received by the semiconductor memory device 1 is stored in the memory cell array 11. In the read operation, the read data DAT is read from the memory cell array 11.

Based on the received address information ADD, the row decoder 12 selects a predetermined block BLK on which various operations such as the read operation and the write operation are executed. The row decoder 12 transmits a voltage to a word line of the selected block BLK.

Based on the received address information ADD, the sense amplifier 13 executes an operation of transmitting the data DAT between the memory controller 2 and the memory cell array 11. That is, in the write operation, the sense amplifier 13 stores the received write data DAT and applies a voltage to a bit line based on the write data DAT. In the read operation, the sense amplifier 13 applies a voltage to a bit line, reads data stored in the memory cell array 11 as the read data DAT, and outputs the read data DAT to the memory controller 2.

### 1.2 Configuration of Memory Cell Array 11

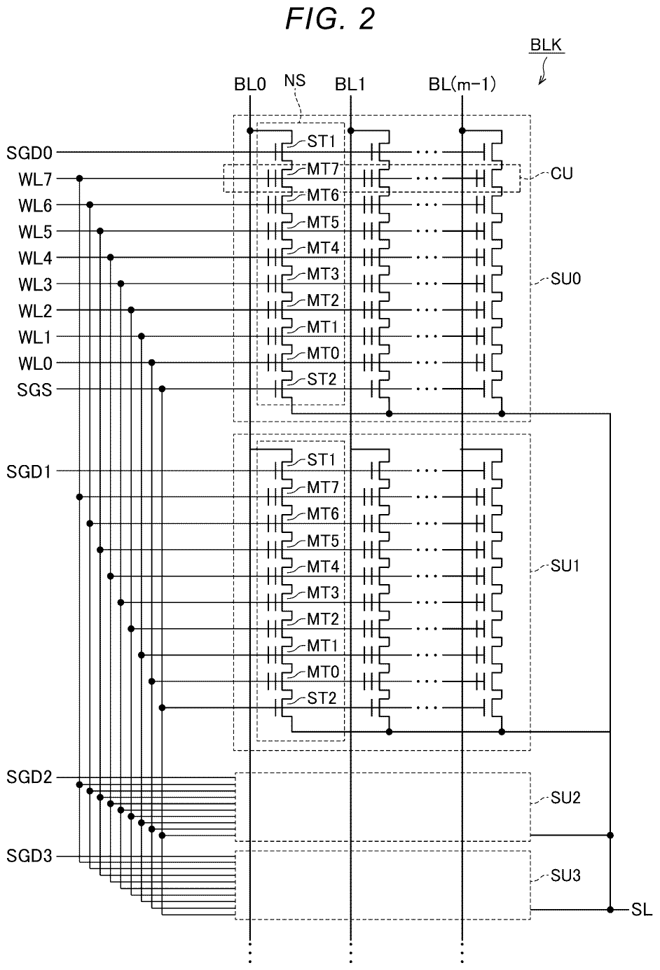

FIG. 2 is a circuit diagram illustrating an example of an equivalent circuit of the memory cell array 11 in the semiconductor memory device 1 according to the first embodiment. As an example of the circuit configuration of the memory cell array 11, an example of a circuit configuration of a predetermined block BLK of the memory cell array 11 is illustrated. Each of other blocks BLK of the memory cell array 11 has the same circuit configuration as that illustrated in FIG. 2.

The block BLK includes, for example, four string units SU0 to SU3. Each of the string units SU includes a plurality of NAND strings NS. The plurality of NAND strings NS are associated with m bit lines BL0 to BL(m-1) (m represents an integer of 1 or more) on a one-to-one basis. Each of the NAND strings NS is connected to the corresponding bit line BL and includes, for example, memory cell transistors MT0 to MT7 and select transistors ST1 and ST2. Each of the memory cell transistors MT includes a control gate (hereinafter, also referred to as a gate) and a charge storage layer, and can store data in a nonvolatile manner. Each of the select transistors ST1 and ST2 is used for selecting the NAND string NS including the select transistors ST1 and ST2 during various operations.

A drain of the select transistor ST1 of each of the NAND strings NS is connected to the bit line BL associated therewith. The memory cell transistors MT0 to MT7 are connected in series between a source of the select transistor ST1 and a drain of the select transistor ST2. A source of the select transistor ST2 is connected to a source line SL.

Gates of the select transistors ST1 of the NAND strings NS in the string units SU0 to SU3 are connected in common to select gate lines SGD0 to SGD3. Gates of the select transistors ST2 of the NAND strings NS in the block BLK are connected in common to a select gate line SGS. Gates of the memory cell transistors MT0 to MT7 of the NAND strings NS in the block BLK are connected in common to word lines WL0 to WL7.

Each of the bit lines BL is connected to the drain of the select transistor ST1 of the corresponding NAND string NS in each of the string units SU of the block BLK. The source line SL is shared between the string units SU of the block BLK by being connected in common to the sources of the select transistors ST2 of the NAND strings NS in the block BLK. For example, even in different blocks BLK, the source line SL is shared between the blocks BLK by being connected in the same manner.

A set that includes memory cell transistors MT that are connected in common to one word line WL in one string unit SU will be referred to as, for example, a cell unit CU. For example, a set that includes 1-bit data having the same level that are stored in the memory cell transistors MT in the cell unit CU will be referred to as “one page data”. For example, when data of a plurality of bits is stored in each of the memory cells using a MLC method or the like, one cell unit CU stores a plurality of “one page data”.

Hereinabove, the circuit configuration of the memory cell array 11 is described. However, the circuit configuration of the memory cell array 11 is not limited to the above-described configuration. For example, the number of string units SU in each of the blocks BLK can also be freely designed to be any number. In addition, the number of memory cell transistors MT and the number of select transistors ST1 and ST2 in each of the NAND strings NS can be designed to be any number, respectively. The number of word lines WL and the number of select gate lines SGD and SGS can be changed based on the number of memory cell transistors MT and the number of select transistors ST1 and ST2 in the NAND string NS, respectively. In the NAND string NS, the memory cell transistors MT can have the same structure, and can also include a dummy memory cell transistor that does not store valid data.

### 1.3 Structure of Semiconductor Memory Device 1

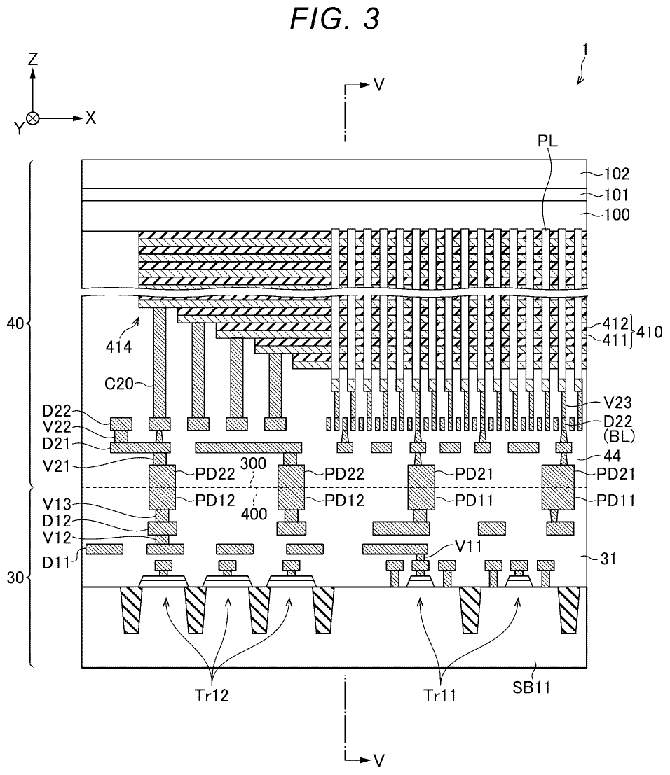

FIG. 3 is a cross-sectional view illustrating an example of a cross-sectional structure of the semiconductor memory device 1 according to the first embodiment. As illustrated in FIG. 3, the semiconductor memory device 1 has a structure where a peripheral circuit chip 30 and a cell chip 40 are bonded in a Z direction. In the peripheral circuit chip 30, the peripheral circuit PRC is provided. In the cell chip 40, a stacked body 410 that functions as a part of the memory cell array 11 is provided.

Hereinafter, for convenience of description, directions are defined based on a semiconductor substrate SB11 in the peripheral circuit chip 30. For example, two directions that are orthogonal to each other and are parallel to a predetermined surface of the semiconductor substrate SB11 are defined as an X direction and a Y direction. A direction that intersects the predetermined surface of the semiconductor substrate SB11 and in which peripheral circuit elements are formed based on the surface is defined as the Z direction. The Z direction is assumed to be orthogonal to the X direction and the Y direction. However, the Z direction is not necessarily limited to this configuration. In the following description, it is assumed that the Z direction is “upward” and a direction opposite to the Z direction is “downward”. However, this expression is merely for convenience of description and does not relate to, for example, the gravity direction.

### 1.3.1 Structure of Peripheral Circuit Chip

The semiconductor substrate SB11 of the peripheral circuit chip 30 includes, for example, silicon (Si). On an upper surface of the semiconductor substrate SB11, a plurality of metal oxide semiconductor (MOS) transistors Tr11 and Tr12 are provided as the peripheral circuit elements in the peripheral circuit PRC. Each of the transistors Tr11 and Tr12 includes a gate insulator that is provided on the upper surface of the semiconductor substrate SB11, a gate electrode that is provided on an upper surface of the gate insulator, and a pair of source/drain regions between which a region of the semiconductor substrate SB11 below the gate insulator is interposed.

Conductive layers D11 and D12 are provided above the transistors Tr11 and Tr12. Each of the conductive layers D11 and D12 includes a plurality of wirings that are insulated from each other. Through the wirings, a source, a drain, and a gate of each of the transistors Tr11 and Tr12 can be electrically connected to other components.

A via V11 is provided above a predetermined source region, a predetermined drain region, and a predetermined gate region of the transistor Tr11. An upper surface of the via V11 is in contact with a predetermined wiring in the conductive layer D11. A via V12 is provided on an upper surface of the predetermined wiring in the conductive layer D11. An upper surface of the via V12 is in contact with a predetermined wiring in the conductive layer D12. A via V13 is provided on an upper surface of the predetermined wiring in the conductive layer D12. A conductive layer PD11 is provided on the upper surface of the via V13.

The conductive layer PD11 includes, for example, a metal material such as copper (Cu). An upper surface of the conductive layer PD11 forms a part of an upper surface 300 of the peripheral circuit chip 30, and is positioned at substantially the same position as the upper surface 300 of the peripheral circuit chip 30 in the Z direction. The conductive layer PD11 functions as an electrode pad used for electrical connection to another chip. Hereinafter, the conductor that functions as the electrode pad provided on the upper surface 300 of the peripheral circuit chip 30 will be referred to as a bonding pad PD11. In addition, a conductor that functions as an electrode pad as described above is represented by reference numeral PD.

On the upper surface 300 of the peripheral circuit chip 30, not only the bonding pad PD11 but also a bonding pad PD12 are provided. The bonding pad PD12 is electrically connected to the transistor Tr12 through the via V13, the conductive layer D12, the via V12, the conductive layer D11, and the via V11.

In the present specification, for example, the via V12 and the wiring in the conductive layer D12 are distinguished from each other but may be integrated. The same can be applied to other vias and conductive layers.

The connection through the wirings in the conductive layers D11 and D12 is merely an example. In the peripheral circuit chip 30, various other vias V11 to V13, wirings in the conductive layers D11 and D12, and bonding pad PD11 similar to the ones described above are also provided. In FIG. 3 for convenience of description, all of the various other vias V11 to V13, wirings in the conductive layers D11 and D12, the bonding pads PD11 and PD12 are not necessarily illustrated.

An interlayer insulating layer 31 is provided between the semiconductor substrate SB11 and the upper surface of the peripheral circuit chip 30. The interlayer insulating layer 31 is provided, for example, in a portion where the transistors Tr11 and Tr12, the vias v11 to V13, the wirings in the conductive layers D11 and D12, and the bonding pads PD11 and PD12 are not provided. The interlayer insulating layer 31 contains, for example, oxygen and silicon (for example, SiO₂). In addition, the interlayer insulating layer 31 may further contain nitrogen or carbon.

### 1.3.2 Structure of Cell chip

A bottom surface 400 of the cell chip 40 is bonded to the upper surface 300 of the peripheral circuit chip 30. The cell chip 40 includes the stacked body 410 that functions as a part of the memory cell array 11. More specifically, each of memory pillars PL in the stacked body 410 functions as, for example, one NAND string NS. The memory pillar PL penetrates the stacked body 410 in the Z direction.

In the stacked body 410, a plurality of conductive layers 411 and a plurality of insulating layers 412 are alternately stacked in the Z direction. The conductive layer 411 is formed in a plate shape to extend in the X direction. The conductive layer 411 may include, for example, a stacked film that includes a barrier conductive film containing nitrogen and titanium (for example, TiN) and a metal film such as tungsten. In addition, the conductive layer 411 may contain, for example, polycrystalline silicon including impurity such as phosphorus (P) or boron (B). The plurality of conductive layers 411 function as, for example, word lines and gate electrodes of a plurality of memory transistors connected to the word lines. The insulating layer 412 contains oxygen and silicon (for example, SiO₂).

One or a plurality of conductive layers 411 of an upper end and a lower end of the stacked body 410 in the Z direction function as, for example, the select gate line SGS on the source side and the select gate line SGD on the drain side. The select gate line SGS on the source side is provided in a region above the stacked body 410, and the select gate line SGD on the drain side is provided in a region below the stacked body 410. The conductive layers 411 disposed between the select gate line SGS on the source side and the select gate line SGD on the drain side functions as the word lines WL.

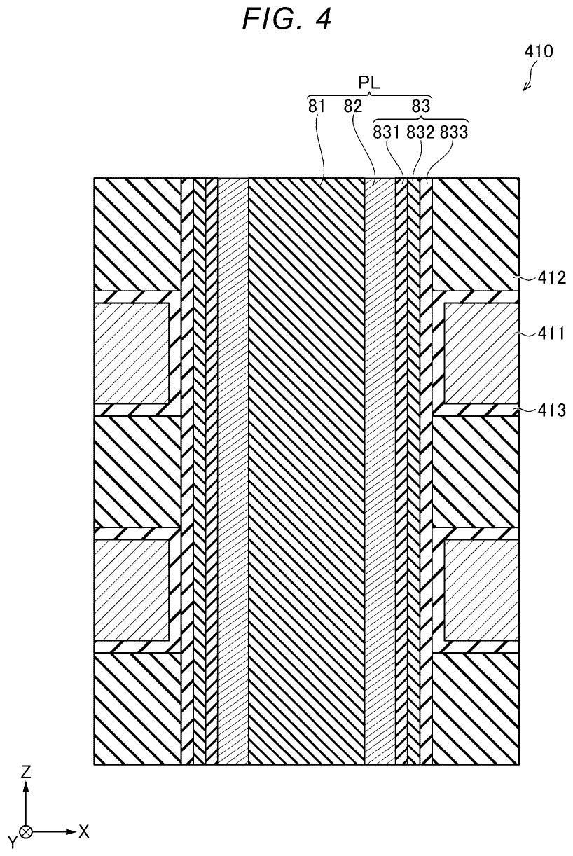

FIG. 4 is an enlarged cross-sectional view illustrating a cross-sectional structure around the memory pillar PL illustrated in FIG. 3. When the memory pillar PL is taken along an XY plane, the memory pillar PL has, for example, a circular or elliptical cross-sectional shape. The memory pillar PL includes a core portion 81, a semiconductor layer 82, and a gate insulating film 83.

The core portion 81 is provided in a center portion of the memory pillar PL and is formed in a substantially columnar shape. As the core portion 81, an insulator containing silicon and oxygen is used.

The semiconductor layer 82 is formed in a substantially cylindrical shape, and surrounds the outer periphery of the core portion 81. As the semiconductor layer 82, for example, polysilicon (Poly-Si) is used. The semiconductor layer 82 is a portion where a channel of the memory cell transistor MT or the like is formed.

The gate insulating film 83 is formed in a substantially cylindrical shape, and surrounds the outer periphery of the semiconductor layer 82. The gate insulating film 83 includes a tunnel insulating film 831, a charge storage film 832, and a block insulating film 833 that are stacked and disposed between the semiconductor layer 82 and the conductive layer 411.

The tunnel insulating film 831 covers the outer periphery of the semiconductor layer 82. As the tunnel insulating film 831, for example, a film containing silicon and oxygen or a film containing silicon, oxygen, and nitrogen is used. The tunnel insulating film 831 functions as a potential barrier between the semiconductor layer 82 and the charge storage film 832. For example, when electrons are injected from the semiconductor layer 82 into the charge storage film 832 (during a write operation), the electrons pass (tunnel) through the potential barrier of the tunnel insulating film 831. In addition, when holes are injected from the semiconductor layer 82 into the charge storage film 832 (during an erasing operation), the holes pass through the potential barrier of the tunnel insulating film 831.

The charge storage film 832 covers the outer periphery of the tunnel insulating film 831. The charge storage film 832 is, for example, a film containing silicon and nitrogen. The charge storage film 832 includes trap sites where charges are trapped in the film. A portion of the charge storage film 832 interposed between the conductive layer 411 and the semiconductor layer 82 is used as a storage area of the memory cell transistor MT.

The block insulating film 833 covers the outer periphery of the charge storage film 832. The block insulating film 833 is a film for reducing back tunneling of charges from the conductive layer 411 to the gate insulating film 83. The block insulating film 833 is, for example, a film containing silicon and oxygen or containing metal and oxygen. The film containing metal and oxygen is, for example, a film containing an aluminum oxide.

The outer periphery of the conductive layer 411 is covered with a barrier insulating film 413. For example, when the tungsten is used as the conductive layer 411, a film having a stacked structure of a film containing silicon and nitrogen and a film containing titanium is selected as the barrier insulating film 413. Instead of the barrier insulating film 413, a conductive film such as a film containing titanium and nitrogen may be used.

A portion of the memory pillar PL positioned inside each of the conductive layer 411, in other words, an intersection with the conductive layer 411, functions as a transistor. That is, the memory pillar PL has a structure where a plurality of transistors are electrically connected in series along a longitudinal direction of the memory pillar PL. Each of the conductive layers 411 functions as a gate of each of the transistors. The semiconductor layer 82 functions as a channel of each of the transistors.

A part of the transistors disposed in series along the longitudinal direction of the memory pillar PL functions as the plurality of memory cell transistors MT illustrated in FIG. 2. In addition, transistors provided at both ends of each of the plurality of memory cell transistors MT disposed in series function as select transistors ST1 and ST2 illustrated in FIG. 2.

As illustrated in FIG. 3, a bonding pad PD21 is provided on the bottom surface 400 of the cell chip 40. The bonding pad PD21 is joined to an upper surface of the bonding pad PD11 of the peripheral circuit chip 30. A bottom surface of each of the bonding pads PD21 forms a part of the bottom surface 400 of the cell chip 40, and is positioned at substantially the same position as the bottom surface 400 of the cell chip 40 in the Z direction. The bonding pad PD21 contains, for example, a metal material such as copper (Cu).

A via V21 is provided on an upper surface of the bonding pad PD21. An upper surface of the via V21 is connected to a predetermined wiring in a conductive layer D21. A via V22 is provided on an upper surface of the predetermined wiring in the conductive layer D21. An upper surface of the via V22 is connected to a predetermined wiring in a conductive layer D22. A via V23 is provided on an upper surface of the predetermined wiring in the conductive layer D22. An upper surface of the via V23 is connected to a lower end of a predetermined memory pillar PL of the stacked body 410. Among the wirings in the conductive layer D22, a wiring electrically connected to the via V23 functions as a part of the bit line BL. The portion of the conductive layer D22 functioning as the bit line BL extends in the Y direction.

In an end portion of the stacked body 410, a step portion 414 is formed. The conductive layer 411 functioning as the word line WL in the step portion 414 is electrically connected to a bonding pad PD22 through a contact C20, the conductive layer D22, the via V22, the conductive layer D21, and the via V21. A bottom surface of the bonding pad PD22 forms a part of the bottom surface 400 of the cell chip 40, and is positioned at substantially the same position as the bottom surface 400 of the cell chip 40 in the Z direction.

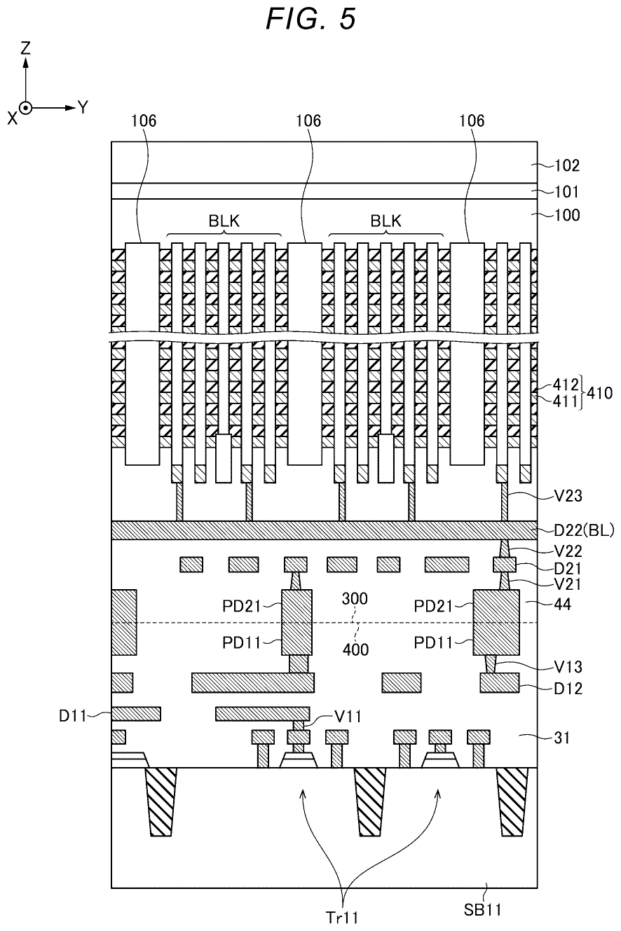

FIG. 5 is a cross-sectional view illustrating a cross-sectional structure taken along line V-V of FIG. 3. As illustrated in FIG. 5, a part of the stacked body 410 is separated into portions in the Y direction by an inter-block insulating layer 106. Each of the portions separated by the inter-block insulating layer 106 forms the block BLK illustrated in FIG. 2.

As illustrated in FIGS. 3 and 5, the cell chip 40 includes a semiconductor layer 100, an insulating layer 101, and an insulating layer 102 in this order above the stacked body 410.

The semiconductor layer 100 is a semiconductor layer of silicon (Si) or the like into which an N-type impurity such as phosphorus (P) or a P-type impurity such as boron (B) is injected. For example, a metal such as tungsten (W) or a silicide such as tungsten silicide (WSi) may be provided between the semiconductor layer 100 and the insulating layer 101. The insulating layer 101 is, for example, an insulating layer containing oxygen and silicon (for example, SiO2). The insulating layer 101 covers, for example, the entire area of the upper surface of the semiconductor layer 100. The insulating layer 102 is, for example, a passivation layer containing polyimide.

In the cell chip 40, an interlayer insulating layer 44 is provided in at least a part of a portion where the bonding pads PD21 and PD22, the vias V21 to V23, the conductive layers D21 and D22, the stacked body 410, and the like are not provided. The interlayer insulating layer 44 contains, for example, oxygen and silicon. In addition, the interlayer insulating layer 44 may further contain nitrogen or carbon.

### 1.3.3 Structure of Bonding Pad

Next, a structure of the bonding pad will be described in detail. A joined structure including the bonding pad PD11 of the peripheral circuit chip 30 and the bonding pad PD21 of the cell chip 40 and a joined structure including the bonding pad PD12 of the peripheral circuit chip 30 and the bonding pad PD22 of the cell chip 40 may be the same as or similar to each other. Therefore, the joined structure including the bonding pad PD11 of the peripheral circuit chip 30 and the bonding pad PD21 of the cell chip 40 will be described below as being representative.

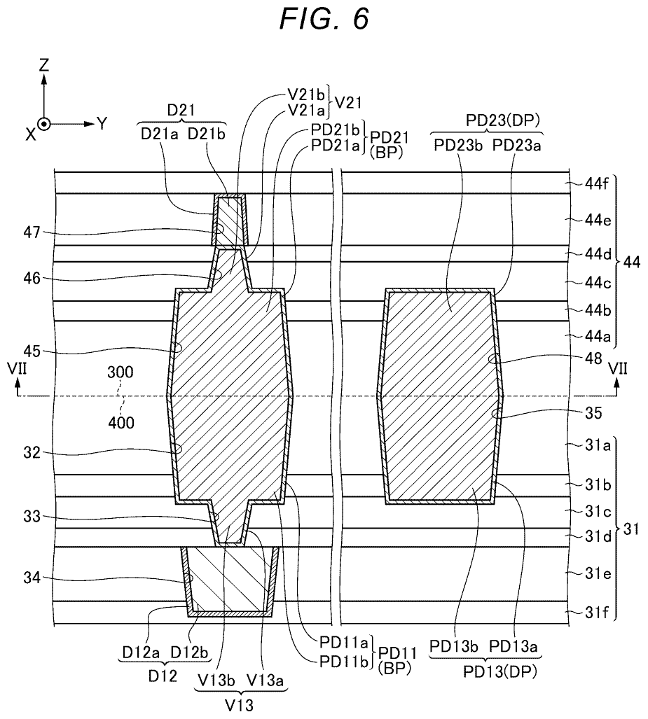

FIG. 6 is a cross-sectional view illustrating a cross-sectional structure around the bonding pad PD21 and a dummy pad DP of the cell chip 40. As illustrated in FIG. 6, the interlayer insulating layer 31 includes insulating layers 31a to 31f. Each of the insulating layers 31a, 31c, and 31e is, for example, an insulating layer containing silicon and oxygen (for example, SiO2) formed using dTEOS. The insulating layer 31b is interposed between the two insulating layers 31a and 31c in the Z direction. The insulating layer 31d is interposed between the two insulating layers 31c and 31e in the Z direction. The insulating layer 31f is disposed below the insulating layer 31e in the Z direction. The insulating layers 31b, 31d, and 31f are, for example, insulating layers containing silicon and nitrogen (for example, SiN).

In the insulating layers 31a and 31b, a recess portion 32 is opened to an upper surface of the insulating layer 31a. In the insulating layers 31c and 31d, a recess portion 33 is opened to a bottom surface of the recess portion 32. In the insulating layers 31e and 31f, a recess portion 34 is opened to a bottom surface of the recess portion 33.

The bonding pad PD11 is embedded in the recess portion 32. The bonding pad PD11 includes a barrier metal layer PD11a and a pad material layer PD11b. The barrier metal layer PD11a is formed in a thin film shape on an inner wall surface and a bottom surface of the recess portion 32. The insulating layers 31a and 31b are provided outside the barrier metal layer PD11a. The pad material layer PD11b is provided inside the recess portion 32 via the barrier metal layer PD11a.

The via V13 is embedded in the recess portion 33. The via V13 includes a barrier metal layer V13a and a via material layer V13b. The barrier metal layer V13a is formed in a thin film shape on an inner wall surface of the recess portion 33 and in a boundary portion between the via V13 and the conductive layer D12. The insulating layers 31c and 31d are provided outside the barrier metal layer V13a. The via material layer V13b is embedded in the recess portion 33 via the barrier metal layer V13a.

The conductive layer D12 is embedded in the recess portion 34. The conductive layer D12 includes a barrier metal layer D12a and a conductive material layer D12b. The barrier metal layer D12a is formed in a thin film shape on an inner wall surface of the recess portion 34. The conductive material layer D12b is embedded in the recess portion 34 via the barrier metal layer D12a.

The interlayer insulating layer 44 includes insulating layers 44a to 44f as in the interlayer insulating layer 31. Each of the insulating layers 44a, 44c, and 44e is, for example, an insulating layer containing silicon and oxygen (for example, SiO2) formed using dTEOS. The insulating layer 44b is interposed between the two insulating layers 44a and 44c in the Z direction. The insulating layer 44d is interposed between the two insulating layers 44c and 44e in the Z direction. The insulating layer 44f is disposed above the insulating layer 44e in the Z direction. The insulating layers 44b, 44d, and 44f are, for example, insulating layers containing silicon and nitrogen (for example, SiN).

In the insulating layers 44a and 44b, a recess portion 45 is opened to a bottom surface of the insulating layer 44a. In the insulating layers 44c and 44d, a recess portion 46 is opened to an upper surface of the recess portion 45. In the insulating layer 44e, a recess portion 47 is opened to an upper surface of the recess portion 46.

The bonding pad PD21 is embedded in the recess portion 45. The bonding pad PD21 includes a barrier metal layer PD21a and a pad material layer PD21b. The barrier metal layer PD21a is formed in a thin film shape on an inner wall surface and an upper surface of the recess portion 45. The insulating layers 44a and 44b are provided outside the barrier metal layer PD21a. The pad material layer PD21b is provided inside the recess portion 45 via the barrier metal layer PD21a. The pad material layer PD21b is joined to the pad material layer PD11b provided below the pad material layer PD21b. That is, the bonding pad PD11 and the bonding pad PD21 are electrically connected to each other.

The via V21 is embedded in the recess portion 46. The via V21 includes a barrier metal layer V21a and a via material layer V21b. The barrier metal layer V21a is formed in a thin film shape on an inner wall surface of the recess portion 46 and in a boundary portion between the via V21 and the conductive layer D21. The insulating layers 44c and 44d are provided outside the barrier metal layer V21a. The via material layer V21b is embedded in the recess portion 46 via the barrier metal layer V21a.

The conductive layer D21 is embedded in the recess portion 47. The conductive layer D21 includes a barrier metal layer D21a and a conductive material layer D21b. The barrier metal layer D21a is formed in a thin film shape on an inner wall surface of the recess portion 47. The conductive material layer D21b is embedded in the recess portion 47 via the barrier metal layer D21a.

In the peripheral circuit chip 30, a recess portion 35 is further opened to the upper surface 300. A pad PD13 is embedded in the recess portion 35. As in the bonding pad PD11, the pad PD13 includes a barrier metal layer PD13a and a pad material layer PD13b. The pad PD13 is different from the bonding pad PD11, and is not connected to the conductive layer D12. The pad PD13 is not illustrated in FIGS. 3 and 5.

In the cell chip 40, a recess portion 48 is further opened to the bottom surface 400. A pad PD23 is embedded in the recess portion 48. As in the bonding pad PD21, the pad PD23 includes a barrier metal layer PD23a and a pad material layer PD23b. The pad PD23 is different from the bonding pad PD21, and is not connected to the conductive layer D21. The pad PD23 is not illustrated in FIGS. 3 and 5.

The pad material layer PD13b of the pad PD13 and the pad material layer PD23b of the pad PD23 are joined to each other. As described above, the pads PD13 and PD23 are not electrically connected to the conductive layers D12 and D21. Therefore, hereinafter, the pads PD13 and PD23 will be referred to as “dummy pads”.

Each of the barrier metal layers D12a, V13a, PD11a, PD13a, PD21a, PD23a, V21a, D21a is, for example, a metal layer containing titanium (Ti) or tantalum (Ta). Each of the pad material layers PD11b, PD13b, PD21b, and PD23b, the via material layers V13b and V21b, and the conductive material layers D12b and D21b is, for example, a metal layer containing Cu.

Hereinafter, the bonding pads PD11 and PD21 joined to each other will be collectively referred to as “bonding pad BP”. In addition, the dummy pads PD13 and PD23 joined to each other will be collectively referred to as “dummy pad DP”.

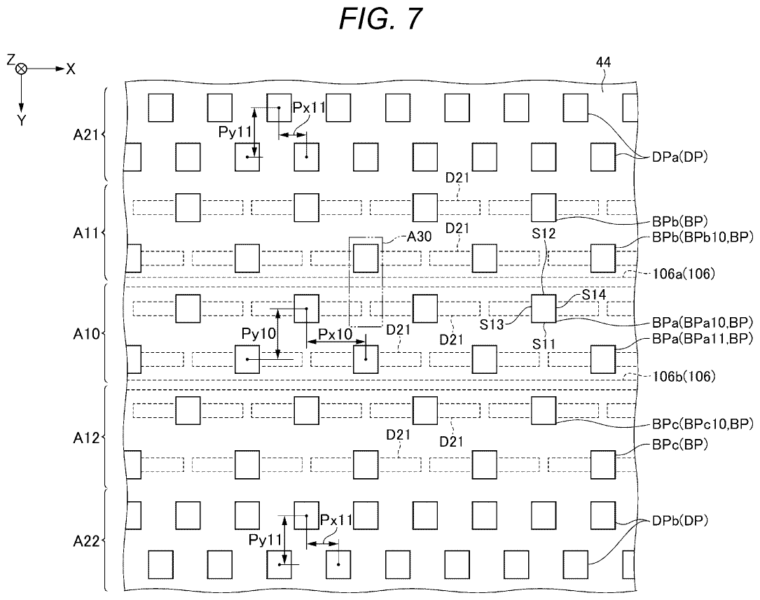

FIG. 7 is a cross-sectional view illustrating a cross-sectional structure taken along line VII-VII of FIG. 6, in other words, the structure of the bottom surface 400 of the cell chip 40. As illustrated in FIG. 7, the bonding pad BP and the dummy pad DP are formed such that a cross-sectional shape orthogonal to the Z direction is a polygonal shape, specifically, a quadrangular shape. More specifically, the bonding pad BP is formed in a quadrangular shape where two sides S11 and S12 facing each other are parallel to each other in the X direction and other two sides S13 and S14 facing each other are parallel to each other in the Y direction. The dummy pad DP has the same shape.

In the cell chip 40, a plurality of inter-block insulating layers 106a and 106b are disposed at predetermined intervals in the Y direction. Each of the inter-block insulating layers 106a and 106b extends in the X direction.

A bonding pad arrangement region A10 is provided between the inter-block insulating layers 106a and 106b. In the bonding pad arrangement region A10, a plurality of bonding pads BPa are disposed in a staggered arrangement in the X direction and the Y direction. The plurality of bonding pads BPa are disposed at a predetermined pitch Px10 in the X direction. The plurality of bonding pads BPa are disposed at a predetermined pitch Py10 in the Y direction. The pitch Px10 and the pitch Py10 are set to, for example, the same value.

In a portion opposite to a portion where the bonding pads BPa are provided with respect to the inter-block insulating layer 106a in the Y direction, a bonding pad arrangement region A11 is provided. In the bonding pad arrangement region A11, a plurality of bonding pads BPb are disposed in a staggered arrangement as in the bonding pad arrangement region A10.

In a portion opposite to a portion where the inter-block insulating layer 106a is provided with respect to the bonding pad arrangement region A11 in the Y direction, a dummy pad arrangement region A21 is provided. In the dummy pad arrangement region A21, a plurality of dummy pads DPa are provided. The dummy pads DPa are disposed in a staggered arrangement in the X direction and the Y direction. The plurality of dummy pads DPa are disposed at a predetermined pitch Px11 in the X direction. The plurality of dummy pads DPa are disposed at a predetermined pitch Py11 in the Y direction. The pitch Px11 and the pitch Py11 are set to, for example, different values.

In a portion opposite to a portion where the bonding pads BPa are provided with respect to the inter-block insulating layer 106b in the Y direction, a bonding pad arrangement region A12 is provided. In the bonding pad arrangement region A12, a plurality of bonding pads BPc are disposed in a staggered arrangement as in the bonding pad arrangement region A10.

In a portion opposite to a portion where the inter-block insulating layer 106b is provided with respect to the bonding pad arrangement region A12 in the Y direction, a dummy pad arrangement region A22 is provided. In the dummy pad arrangement region A22, a plurality of dummy pads DPb are disposed in a staggered arrangement as in the dummy pad arrangement region A21.

In FIG. 7, among the plurality of bonding pads BPa disposed in the bonding pad arrangement region A10, bonding pads BPa disposed adjacent to the inter-block insulating layer 106a are represented by reference numeral BPa10. In addition, among the plurality of bonding pads BPb disposed in the bonding pad arrangement region A11, bonding pads BPb disposed adjacent to the inter-block insulating layer 106a are represented by reference numeral BPb10. The plurality of bonding pads BPa10 and the plurality of bonding pads BPb10 are disposed in a staggered arrangement in the X direction and the Y direction. The plurality of bonding pads BPa10 and the plurality of bonding pads BPb10 are disposed at the predetermined pitch Px10 in the X direction. The plurality of bonding pads BPa10 and the plurality of bonding pads BPb10 are disposed at the predetermined pitch Py10 in the Y direction.

In FIG. 7, among the plurality of bonding pads BPa disposed in the bonding pad arrangement region A10, bonding pads disposed adjacent to the inter-block insulating layer 106b are represented by reference numeral BPa11. In addition, among the plurality of bonding pads BPc disposed in the bonding pad arrangement region A12, bonding pads BPc disposed adjacent to the inter-block insulating layer 106b are represented by reference numeral BPc10. The plurality of bonding pads BPa11 and the plurality of bonding pads BPc10 are also disposed in a staggered arrangement in the X direction and the Y direction as in the bonding pads BPa10 and BPb10.

### 1.4 Operation and Effect of Semiconductor Memory Device According to Present Embodiment

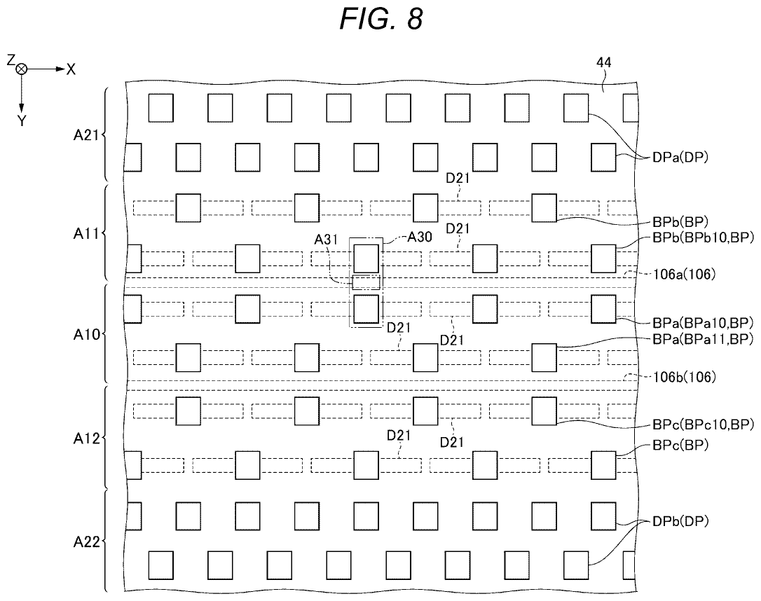

FIG. 8 is a cross-sectional view illustrating a cross-sectional structure of a semiconductor memory device 200 according to a comparative example. In the semiconductor memory device 200 according to the comparative example illustrated in FIG. 8, the plurality of bonding pads BPa10 disposed in the bonding pad arrangement region A10 and the plurality of bonding pads BPb10 disposed in the bonding pad arrangement region A11 are disposed adjacent to each other in the Y direction. In this arrangement, the bonding pads BPa10 and the bonding pads BPb10 are disposed adjacent to each other. Therefore, for example, a coverage of the bonding pads BPa10 and BPb10 in a region A30 indicated by a two-dot chain line in FIG. 8 increases. The coverage refers to a ratio of the area of the pads such as the bonding pads BPa10 and BPB10 to the total area of the region indicated by the two-dot chain line. When the coverage of the bonding pads BPa10 and BPb10 increases, for example, during polishing of the bottom surface 400 of the cell chip 40 using chemical mechanical polishing (CMP) or the like, a region A31 disposed between the bonding pads BPa10 and the bonding pads BPb10 in the interlayer insulating layer 44 may be further removed. Even during the polishing of the upper surface 300 of the peripheral circuit chip 30 using CMP or the like, the same problem may occur. When the region A31 is further removed, voids are formed in this portion, which may cause product defects.

To address the above problem, in the semiconductor memory device 1 according to the present embodiment, the plurality of bonding pads BPa10 and the plurality of bonding pads BPb10, which are disposed with the inter-block insulating layer 106a disposed therebetween, are disposed in a staggered arrangement in the X direction and the Y direction as illustrated in FIG. 7. In other words, the plurality of bonding pads BPa10 and the plurality of bonding pads BPb10 are alternately provided in the X direction and are alternately provided in the Y direction.

In this configuration, the coverage of the bonding pads BPa10 and BPb10 in the region A30 indicated by the two-dot chain line in FIG. 7 can be reduced. As a result, the formation of voids in the region A30 can be reduced.

### 2. SECOND EMBODIMENT

Next, a second embodiment of the semiconductor memory device 1 will be described. Hereinafter, a difference from the semiconductor memory device 1 according to the first embodiment will be mainly described.

### 2.1 Structure of Bonding pad

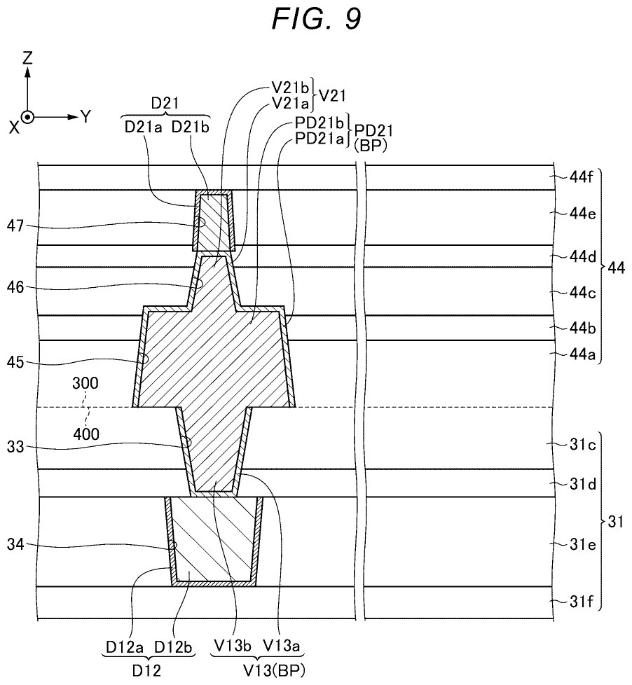

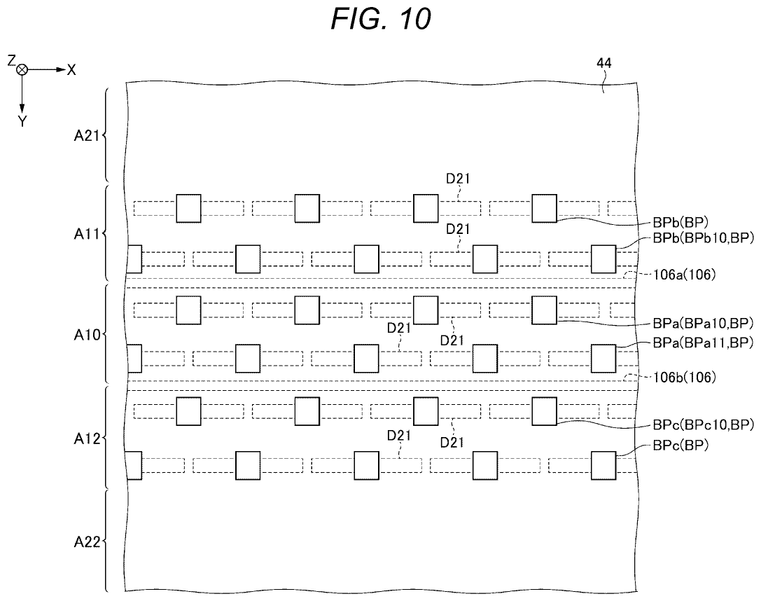

FIG. 9 is a cross-sectional view illustrating a cross-sectional structure around the bonding pad PD21 of the cell chip 40 according to the present embodiment. FIG. 10 is a cross-sectional view illustrating a cross-sectional structure of the cell chip 40 according to the present embodiment corresponding to the cross-sectional structure taken along line VII-VII of FIG. 6. As illustrated in FIG. 9, the bonding pad PD11 is not provided in the peripheral circuit chip 30 according to the present embodiment. The via V13 is exposed to the upper surface 300 of the peripheral circuit chip 30. The via V13 is joined to the bonding pad PD21 of the cell chip 40. In the present embodiment, the bonding pad BP includes the via V13 and the bonding pad PD21.

The semiconductor memory device 1 according to the present embodiment is different from the semiconductor memory device 1 according to the first embodiment, in that the dummy pad DP is not provided. Accordingly, as illustrated in FIG. 10, the dummy pads DPa and DPb are not disposed in the dummy pad arrangement regions A21 and A22.

### 2.2 Operation and Effect of Semiconductor Memory Device According to Present Embodiment

In the semiconductor memory device 1 according to the first embodiment, as illustrated in FIGS. 6 and 7, the dummy pad DP is provided in the portion where the bottom surface 400 of the cell chip 40 and the upper surface 300 of the peripheral circuit chip 30 are bonded to each other. On the other hand, in the semiconductor memory device 1 according to the present embodiment, as illustrated in FIGS. 9 and 10, the dummy pad DP is not provided in the portion where the bottom surface 400 of the cell chip 40 and the upper surface 300 of the peripheral circuit chip 30 are bonded to each other.

In this configuration, the dummy pad DP is not disposed in the dummy pad arrangement region A22. Therefore, for example, a coverage difference that is a difference between the coverage of the pads in the bonding pad arrangement region A12 where the bonding pads BPc are disposed and the coverage of the pads in the dummy pad arrangement region A22 can be increased. As a result, the formation of voids in a bonding surface of the cell chip 40 and the peripheral circuit chip 30 can be further reduced.

### First Modification Example

Next, a first modification example of the semiconductor memory device 1 according to the second embodiment will be described.

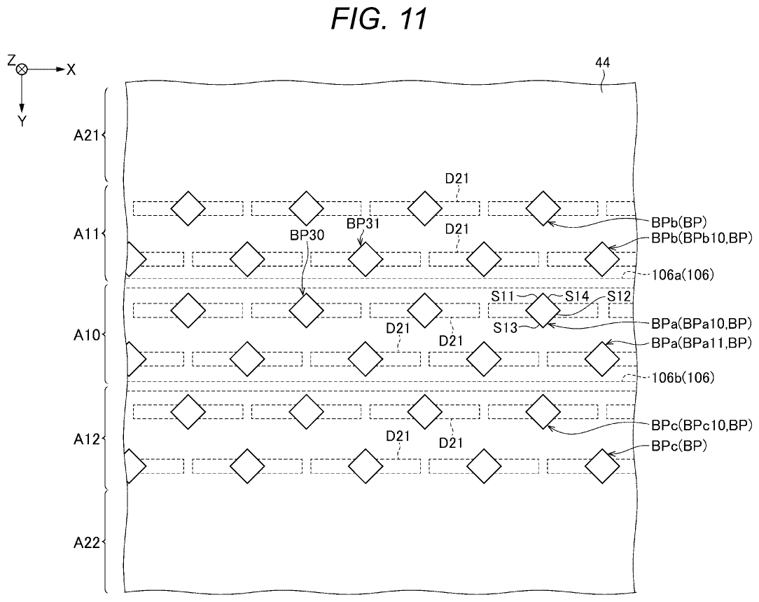

FIG. 11 is a cross-sectional view illustrating a cross-sectional structure of the cell chip 40 according to the present embodiment corresponding to the cross-sectional structure taken along line VII-VII of FIG. 6. As illustrated in FIG. 11, the bonding pad BP according to the present modification example is formed such that a cross-sectional shape orthogonal to the Z direction is a quadrangular shape where the two sides S11 and S12 facing each other intersect with the X direction at an angle of 45 degrees and the other two sides S13 and S14 facing each other intersect with the Y direction at an angle of 45 degrees.

In this configuration, among the plurality of bonding pads BP, for example, the distance between a bonding pad BP30 and a bonding pad BP31 disposed adjacent to each other can be increased. Therefore, the formation of voids in a region between the bonding pad BP30 and the bonding pad BP31 can be reduced.

### Second Modification Example

Next, a second modification example of the semiconductor memory device 1 according to the second embodiment will be described.

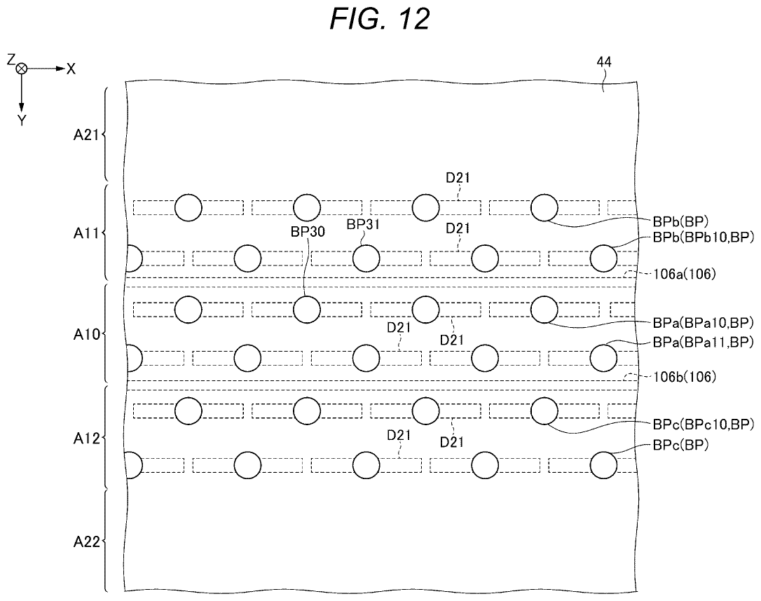

FIG. 12 is a cross-sectional view illustrating a cross-sectional structure of the cell chip 40 according to the present embodiment corresponding to the cross-sectional structure taken along line VII-VII of FIG. 6. As illustrated in FIG. 12, the bonding pad BP according to the present modification example is formed such that a cross-sectional shape orthogonal to the Z direction is a circular shape. In this configuration, among the plurality of bonding pads BP, for example, the distance between a bonding pad BP30 and a bonding pad BP31 disposed adjacent to each other can be increased. Therefore, the formation of voids in a region between the bonding pad BP30 and the bonding pad BP31 can be reduced.

### Third Modification Example

Next, a third modification example of the semiconductor memory device 1 according to the second embodiment will be described.

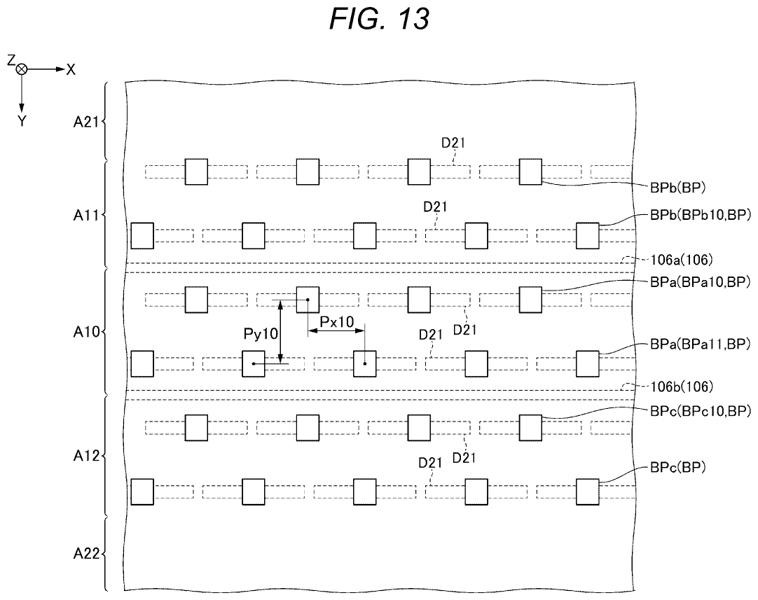

FIG. 13 is a cross-sectional view illustrating a cross-sectional structure of the cell chip 40 according to the present embodiment corresponding to the cross-sectional structure taken along line VII-VII of FIG. 6. As illustrated in FIG. 13, in the semiconductor memory device 1 according to the present modification example, the pitch Px10 and the pitch Py10 are set to different values. Even in this configuration, the same or similar operation and effect as or to those of the semiconductor memory device 1 according to the second embodiment can be obtained.

### 3. OTHER EMBODIMENTS

The present disclosure is not limited to the above-described specific examples.

For example, the inter-block insulating layer 106 illustrated in FIG. 5 is formed to cut the stacked body 410 in the Z direction, more specifically, to cut all of the conductive layers 411 functioning as the select gate line SGS, the word lines WL, and the select gate line SGD. Alternately, the inter-block insulating layer 106 may be formed in the stacked body 410 to cut only the conductive layer 411 functioning as the select gate line SGD.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first chip having a first bonding surface; and
a second chip having a second bonding surface and bonded to the first chip, wherein
the first chip includes
a stacked body where a plurality of first conductive layers and a plurality of first insulating layers are alternately stacked in a first direction,
a memory pillar that penetrates the stacked body in the first direction to form memory cell transistors at intersections with the first conductive layers, and
a plurality of first bonding electrodes provided on the first bonding surface and to which the second chip is bonded,
the second chip includes a plurality of second bonding electrodes provided on the second bonding surface and to which the first chip is bonded,
the plurality of first bonding electrodes and the plurality of second bonding electrodes are joined to each other to form a plurality of joining electrodes,
the stacked body extends in a second direction intersecting with the first direction and includes a second insulating layer that extends in the first direction in the stacked body such that at least a part of the stacked body is separated in a third direction intersecting with both of the first direction and the second direction,
the plurality of joining electrodes include a plurality of first joining electrodes and a plurality of second joining electrodes, the first joining electrodes being disposed adjacent to a first side of the second insulating layer in the third direction and at a first predetermined interval along the second direction, and the second joining electrodes being disposed adjacent to a second side of the second insulating layer in the third direction and at a second predetermined interval along the second direction, and
the plurality of first joining electrodes and the plurality of second joining electrodes are disposed in a staggered arrangement in the second direction and the third direction.

2. The semiconductor memory device according to claim 1, wherein
the first chip further includes a second conductive layer that is electrically connected to one of the first bonding electrodes through a first via, and the second chip further includes a third conductive layer that is electrically connected to one of the second bonding electrodes through a second via.

3. The semiconductor memory device according to claim 1, wherein
the first chip further includes a second conductive layer that is electrically connected to one of the first bonding electrodes, and the second chip further includes a third conductive layer that is electrically connected to one of the second bonding electrodes, and
in a portion where the first bonding surface of the first chip and the second bonding surface of the second chip are bonded to each other, a dummy electrode that is not electrically connected to either the second conductive layer or the third conductive layer is further provided.

4. The semiconductor memory device according to claim 1, wherein
the first chip further includes a second conductive layer that is electrically connected to one of the first bonding electrodes, and the second chip further includes a third conductive layer that is electrically connected to one of the second bonding electrodes, and
in a portion where the first bonding surface of the first chip and the second bonding surface of the second chip are bonded to each other, a dummy electrode that is not electrically connected to either the second conductive layer or the third conductive layer is not provided.

5. The semiconductor memory device according to claim 1, wherein the first predetermined interval is equal to the second predetermined interval.

6. The semiconductor memory device according to claim 5, wherein the plurality of first joining electrodes are aligned in the second direction along a first imaginary line and the plurality of second joining electrodes are aligned in the second direction along a second imaginary line, and a distance between the first and second imaginary lines in the third direction is equal to the first predetermined interval.

7. The semiconductor memory device according to claim 5, wherein the plurality of first joining electrodes are aligned in the second direction along a first imaginary line and the plurality of second joining electrodes are aligned in the second direction along a second imaginary line, and a distance between the first and second imaginary lines in the third direction is not equal to the first predetermined interval.

8. The semiconductor memory device according to claim 1, wherein a cross-section of each of the joining electrodes taken orthogonal to the first direction has a polygonal shape.

9. The semiconductor memory device according to claim 8, wherein the polygonal shape is a quadrangular shape.

10. The semiconductor memory device according to claim 9, wherein parallel sides of each of the joining electrodes extend in the second direction or the third direction.

11. The semiconductor memory device according to claim 9, wherein parallel sides of each of the joining electrodes extend obliquely with respect to the second direction and the third direction.

12. The semiconductor memory device according to claim 1, wherein a cross-section of each of the joining electrodes has a circular shape.

13. A semiconductor memory device comprising:
first and second chips that are bonded together at respective first and second bonding surfaces thereof, wherein
the first chip includes a stacked body where a plurality of first conductive layers and a plurality of first insulating layers are alternately stacked in a first direction, a memory pillar that penetrates the stacked body in the first direction to form memory cell transistors at intersections with the first conductive layers, and a plurality of first electrodes provided on the first bonding surface,
the second chip includes a plurality of second electrodes provided on the second bonding surface,
the plurality of first electrodes includes a plurality of bonding pads, each of which is bonded to one of the second electrodes,
the stacked body extends in a second direction intersecting with the first direction and includes a second insulating layer that extends in the first direction in the stacked body such that at least a part of the stacked body is separated in a third direction intersecting with both of the first direction and the second direction,
the plurality of bonding pads include a plurality of first bonding pads and a plurality of second bonding pads, the first bonding pads being disposed adjacent to a first side of the second insulating layer in the third direction and at a first predetermined interval along the second direction, and the second bonding pads being disposed adjacent to a second side of the second insulating layer in the third direction and at a second predetermined interval along the second direction, and
the plurality of first bonding pads and the plurality of second bonding pads are disposed in a staggered arrangement in the second direction and the third direction.

14. The semiconductor memory device according to claim 13, wherein the plurality of second electrodes includes a plurality of bonding pads, and the bonding pads of the first chip are respectively bonded to the bonding pads of the second chip.

15. The semiconductor memory device according to claim 13, wherein the plurality of second electrodes includes a plurality of vias, and the bonding pads of the first chip are respectively bonded to the vias of the second chip.

16. The semiconductor memory device according to claim 13, wherein the first chip further includes a second conductive layer, and the plurality of bonding pads includes a plurality first bonding pads that are electrically connected to the second conductive layer and a plurality of second bonding pads that are not electrically connected to the second conductive layer.

17. The semiconductor memory device according to claim 16, wherein the first bonding pads are closer to the second insulating layer than the second bonding pads.

18. The semiconductor memory device according to claim 13, wherein the first predetermined interval is equal to the second predetermined interval.

19. The semiconductor memory device according to claim 18, wherein the plurality of first bonding pads are aligned in the second direction along a first imaginary line and the plurality of second bonding pads are aligned in the second direction along a second imaginary line, and a distance between the first and second imaginary lines in the third direction is equal to the first predetermined interval.

20. The semiconductor memory device according to claim 18, wherein the plurality of first bonding pads are aligned in the second direction along a first imaginary line and the plurality of second bonding pads are aligned in the second direction along a second imaginary line, and a distance between the first and second imaginary lines in the third direction is not equal to the first predetermined interval.
